(19) United States
(12) Patent Application Publication
(10) Pub. No.: US 2001/0009224 A1
(43) Pub. Date: Jul. 26, 2001

(54) Planar-type magnetron sputtering apparatus

(76) Inventors: Jeon-geon Han, Seoul (KR); Kyung-hoon Nam, Seoul (KR); Jindrich Musil, Machova (CZ)

Correspondence Address: Paul A. Taufer, Schnader Harrison Segal & Lewis LLP, Suite 3600, 1600 Market Street, Philadelphia, PA, 19103, US

(21) Appl. No.: 09/768,378

(22) Filed: Jan. 23, 2001

(30) Foreign Application Priority Data
Jan. 24, 2000 (KR) 10-2000-3269

(51) Int. Cl. C23C 14/34

(52) U.S. Cl. 204/298.2; 204/298.19; 204/298.12; 204/298.09

(57) ABSTRACT

A planar-type magnetron sputtering apparatus capable of forming a uniform thin coating on the entire surface of a substrate having a large area is disclosed. This sputtering apparatus has an insulating target seat, a permanent magnet closed circuit unit consisting of at least two permanent magnet closed circuits, and used for applying an electric field to the target, and a closed circuit moving unit used for continuously moving the permanent magnet closed circuit unit in one direction along an elliptical track parallel to the surface of the target. Due to the movement of permanent magnet closed circuits in one direction, the magnetron discharge tracks continuously moves along the target surface in the same direction. This sputtering apparatus thus allows the target to be uniformly etched on its surface. It is thus possible to form a desired uniform thin coating on the entire surface of a substrate having a large area. This apparatus also improves the using efficiency of the expensive target to a desired level of higher than 60% since the target is uniformly etched on its surface due to the unidirectional movement of the permanent magnet closed circuits.

### BACKGROUND OF THE INVENTION

1. Field of the Invention

The present invention relates to an apparatus for physically forming a thin coating on a substrate surface through a sputtering process and, more particularly, to a planar-type magnetron sputtering apparatus capable of forming a uniform thin coating on the entire surface of a substrate having a large area.

2. Description of the Prior Art

As well known to those skilled in the art, a magnetron sputtering process has been used for forming a thin coating on a substrate surface. Since such a magnetron sputtering process is advantageous in that it can be performed at a lower temperature environment and can effectively form a thin coating having a desired appearance on a substrate surface, it has been widely used in the sputtering field.

The conventional magnetron sputtering process is a kind of physical vapor deposition process, which increases both the ionization ratio and the sputtering ratio at a position around a target. The conventional magnetron sputtering process thus provides a thin coating deposited on a substrate surface with a high adherent force, a desired surface and a high density of the coating.

When both an electric field and a magnetic field are formed around a target so as to allow the target to perform a magnetron discharge, electrons are discharged from the target while creating both a swirling motion and a hopping motion at a position around a predetermined portion of the target surface in accordance with the electric field, the magnetic field and the velocity of discharged electrons. In such a case, both the ionization ratio and the sputtering ratio are increased at the portion of the target with partially concentrated electrons. Therefore, it is necessary to properly control the electric field and the magnetic field during a magnetron sputtering process so as to use the target as a highly efficient magnetron coating source. Of the two fields, it is particularly important to properly control the magnetic field during a sputtering process.

FIG. 1a is a sectional view, showing the construction of a conventional planar-type magnetron sputtering apparatus. As shown in the drawing, the conventional planar-type magnetron sputtering apparatus forms one large-scaled elliptical magnetic field closed circuit 4 around the surface of a cathode target 2 using a permanent magnet 3. A magnetron discharge track is formed along the closed circuit 4, and so the target 2 is partially sputtered and etched at a portion corresponding to the discharge track.

However, the magnetron discharge track formed by the permanent magnet 3 is a fixed track, and so the target 2 is undesirably and partially etched at a position around an area 5 with a high density plasma. The etching rate is also partially accelerated at the position 6 of the target 2 around said area 5. Therefore, the target 2 is concentratively etched at said position 6 around the area 5, thus forming a V-shaped etching valley “D” as best seen in FIG. 1b. When such a conventional magnetron sputtering apparatus is used for forming a thin coating on the entire surface of a substrate having a large area, it is almost impossible to form a uniform coating. In addition, the partially and heavily etched target 2 of FIG. 1b is not usable in a next sputtering process, and so the conventional magnetron sputtering apparatus excessively wastes targets such that it only provides a low target using efficiency of no higher than 30%.

In an effort to overcome such problems experienced by the conventional magnetron sputtering apparatus, somewhat improved magnetron sputtering apparatuses capable of improving both the target using efficiency and the uniformity of a thin coating deposited on a substrate surface have been proposed as disclosed in U.S. Pat. Nos. 5,873,989 and 5,855,744. In the above U.S. sputtering apparatuses, a plurality of magnetic field closed circuits are formed around the surface of a cathode target using a plurality of permanent magnets, thus creating a plurality of magnetron discharge tracks on the entire surface of the target. The magnetic field closed circuits are also designed to move in opposite directions along the target while retaining their parallel spaces from the target surface, thus allowing the magnetron discharge tracks to move on the entire surface of the target in the same directions as those of the closed circuits. The U.S. sputtering apparatuses thus improve the uniformity of the thin coating deposited on the surface of the substrate in addition to improving the target using efficiency.

In the above U.S. magnetron sputtering apparatuses with the movable closed circuits, the opposite directional movement of said closed circuits is accomplished by either the rotating force of a motor-operated screw or the rotating force of a motor-operated eccentric shaft.

However, such a magnetron sputtering apparatus with the movable closed circuits is problematic in that it is almost impossible to move the permanent magnet closed circuits at desired high speeds during an opposite directional movement of the closed circuits. In addition, in order to accomplish the opposite directional movement of the permanent magnet closed circuits, each of said sputtering apparatuses necessarily uses a reversible motor, which must repeatedly and frequently change its rotating direction during operation of the sputtering apparatus. However, the reversible motor is easily overloaded and this reduces its expected life span.

The closed circuits are also repeatedly and temporarily stopped at the time the reversible motor changes its rotating direction, and so the magnetron discharge time at opposite end portions of the target is longer than that of the middle portion of the target. Therefore, the sputtering apparatuses only provide an inferior uniformity of the thin coating deposited on the substrate surface and an inferior target efficiency of no higher than 50%.

Furthermore, the reversible motor is rotated at a constant velocity, while there is a difference in the linear velocity of the eccentric shaft during a movement of the eccentric shaft, thus causing the magnetron discharge time at the end portions of the target to be longer than that of the middle portion of the target. Therefore, the U.S. sputtering apparatuses cannot uniformly etch the target or accomplish a desired uniformity of the thin coatings deposited on the substrate surfaces.

### SUMMARY OF THE INVENTION

Accordingly, the present invention has been made keeping in mind the above problems occurring in the prior art, and an object of an embodiment of the present invention is to provide a planar-type magnetron sputtering apparatus, which effectively forms a uniform thin coating on the entire surface of a substrate having a large area.

Another object of an embodiment of the present invention is to provide a planar-type magnetron sputtering apparatus, which improves the target using efficiency during a sputtering process.

A further object of an embodiment of the present invention is to provide a planar-type magnetron sputtering apparatus, which lengthens the expected life span of a means for moving the permanent magnets during an operation of the sputtering apparatus.

Still another object of an embodiment of the present invention is to provide a planar-type magnetron sputtering apparatus, which is designed to allow a target to be uniformly etched for the same discharge time regardless of the portions of the target from one end to the other end of said target during a sputtering process.

In order to accomplish the above objects, the present invention provides an embodiment of a planar-type magnetron sputtering apparatus, comprising a target seat used for seating and holding a target, selected from metal targets of titanium (Ti), chrome (Cr), aluminum (Al), copper (Cu) or zirconium (Zr), or ceramic targets of indium tin oxide (ITO) or aluminum oxide (Al₂O₃), thereon in addition to insulating the target from surrounding conductive parts, a permanent magnet closed circuit unit consisting of at least two permanent magnet closed circuits positioned in parallel to the surface of the target, and used for applying an electric field to the target, and a closed circuit moving unit used for continuously moving the permanent magnet closed circuit unit in one direction along an elliptical track parallel to the surface of the target.

In the above sputtering apparatus, the target is held and insulated by the target seat. In addition, a cooling unit may be selectively installed under the target to cool the target, and a shielding unit may be selectively installed at a position above the target so as to intercept ions discharged from both the cooling unit and the target and prevent an undesired fracture of the insulating target seat due to the ions.

The planar-type magnetron sputtering apparatus of this embodiment further comprises a tension control unit controlling the tension of the permanent magnet closed circuit unit while overcoming a repulsion force acting between the permanent magnet closed circuits, and allowing the permanent magnet closed circuits to maintain a desired parallel space between the closed circuits and the back surface of the target.

### BRIEF DESCRIPTION OF THE DRAWINGS

The above and other objects, features and other advantages of various embodiments of the present invention will be more clearly understood from the following detailed description taken in conjunction with the accompanying drawings, in which:

FIG. 1a is a sectional view, showing the construction of a conventional planar-type magnetron sputtering apparatus;

FIG. 1b is a sectional view of part of a target partially and heavily etched in a sputtering process using the conventional apparatus of FIG. 1;

FIG. 2 is a view, showing the construction of part of a planar-type magnetron sputtering apparatus in accordance with the preferred embodiment of the present invention;

FIG. 3 is a bottom view of a closed circuit moving unit included in the magnetron sputtering apparatus of FIG. 2; and

FIG. 4 is a sectional view, showing the construction of each permanent magnet closed circuit included in the magnetron sputtering apparatus of FIG. 2.

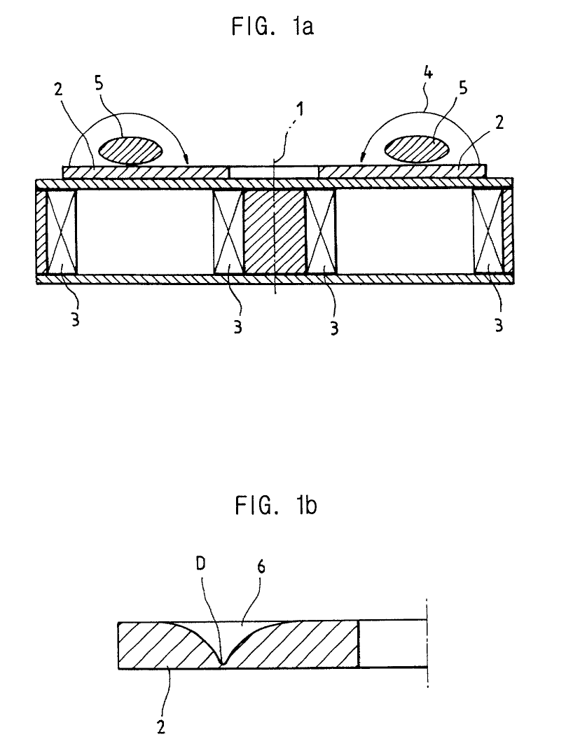

### DETAILED DESCRIPTION OF THE INVENTION

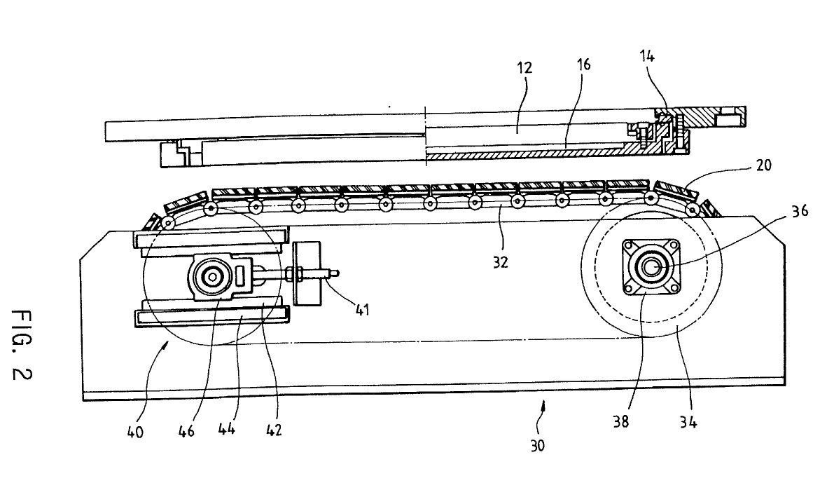

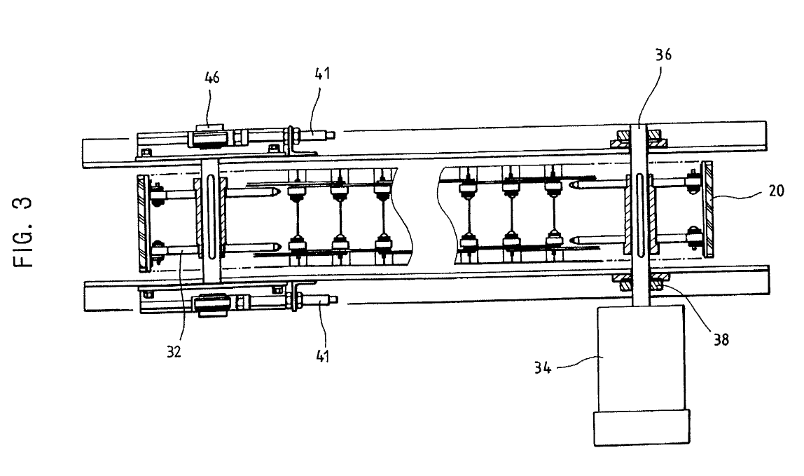

FIG. 2 is a view, showing the construction of part of a planar-type magnetron sputtering apparatus in accordance with the preferred embodiment of the present invention. FIG. 3 is a bottom view of a closed circuit moving unit included in the magnetron sputtering apparatus of FIG. 2.

As shown in the drawings, the magnetron sputtering apparatus of this embodiment comprises a target seat 14, which is made of an insulating Teflon material and is used for seating and holding a cathode target 12 thereon. The target 12 is a metal or ceramic target, and is used for discharging atoms to form a desired thin coating on a substrate surface through a sputtering processing using the apparatus. A cooling unit 16 is installed at a position under the target 12 so as to cool said target 12 during an operation of the apparatus. A permanent magnet closed circuit unit 20, consisting of a plurality of permanent magnet closed circuits 21, is installed under the cooling unit 16 such that the closed circuit unit 20 is spaced apart from the lower surface of the cooling unit 16 by a predetermined gap. This permanent magnet closed circuit unit 20 is used for applying an electric field to the target 12. The sputtering apparatus of this embodiment also comprises a closed circuit moving unit 30, which moves the closed circuit unit 20 in one direction along an elliptical track parallel to the surface of the target 12. The apparatus may be selectively provided with a tension control unit 40, which appropriately controls the tension of the circuit unit 20 while overcoming the repulsion force acting between the closed circuits of the circuit unit 20 and allows the permanent magnet closed circuits 21 of the circuit unit 20 to move in parallel to the surface of the target 12 while maintaining a desired parallel space between the closed circuits 21 and the target 12.

A substrate holder (not shown) is installed at the upper portion of the sputtering apparatus at a position above the target 12, and seats and holds a substrate thereon.

The cathode target 12 is a crystalline material, which has the same components as those of a desired thin coating to be formed on the surface of the substrate. The electrons, discharged from the target 12 in response to an electric field, collide against sputtering gas, such as argon gas (Ar), thus generating argon cations. The argon cations collide with the target 12, thus allowing the target 12 to perform a desired magnetron discharge. That is, the target 12 dislodges atoms and ions from its surface. In the sputtering process, it is possible to use targets of a variety of crystalline materials, such as metal and ceramic materials. In the present embodiment, it is possible to use metal targets of titanium (Ti) , chrome (Cr), aluminum (Al), copper (Cu) or zirconium (Zr), or ceramic targets of indium tin oxide (ITO) or aluminum oxide (alumina, Al₂O₃). In order to form a desired electric field, a negative charge is applied to the target 12, while no charge or a positive charge is applied to the substrate holder positioned opposite to the target 12.

The target seat 14 surrounds the target 12 so as to hold the target 12 in addition to insulating the target 12 from surrounding conductive parts.

The cooling unit 16, positioned under the target 12, cools both the target 12 and the target seat 14 to a desired temperature lower than a predetermined reference point during a sputtering process. Of course, it should be understood that the sputtering apparatus of this embodiment may be designed to be free from such a cooling unit 16. However, it is preferable to install the unit 16 in the apparatus to improve the operational effect of the apparatus. The cooling unit 16 is also provided with a coolant circulation pipe for allowing a circulation of coolant relative to the cooling unit 16.

The permanent magnet closed circuit unit 20 forms a plurality of magnetic fields, for example, two magnetic fields, so as to allow a concentration of electrons, discharged from the target 12, on the surface of the target 12.

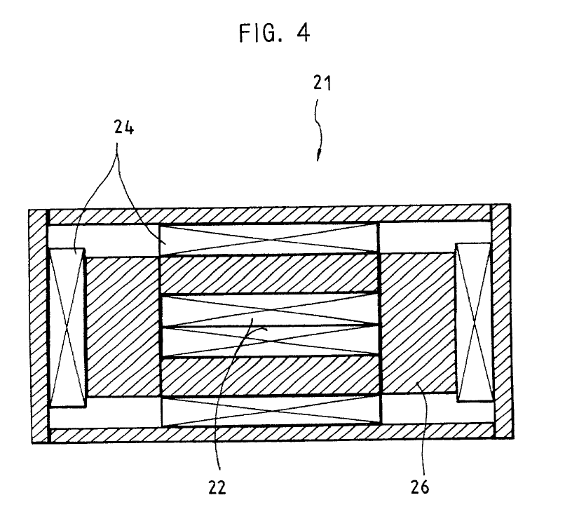

FIG. 4 is a sectional view, showing the construction of each permanent magnet closed circuit 21 included in the closed circuit unit 20 of this invention. As shown in the drawing, each permanent magnet closed circuit 21 of the circuit unit 20 comprises two first permanent magnets 22, which are closely arranged at the central portion of the closed circuit 21. Four second permanent magnets 24 are arranged in each closed circuit 21 at four positions around the two first magnets 22, with four nonmagnetic spacers 16 made of an aluminum alloy and arranged between the first and second magnets 22 and 24 so as to maintain a desired space between the first and second magnets 22 and 24. The aluminum alloy spacers 26 also lighten the weight of the closed circuit 21. In the permanent magnet closed circuit 21, the first and second permanent magnets 22 and 24 are made of a neodymium-iron based alloy (Nd-Fe alloy) or a samarium based alloy (Sm alloy), and have a surface magnetic field of higher than about 2,000 Gauss.

In each permanent magnet closed circuit 21, the two first permanent magnets 22 are arranged such that their N-poles and S-poles are positioned at the same directions. On the other hand, the four second permanent magnets 24 are arranged such that an attraction force acts between the first and second magnets 22 and 24. That is, the second magnets 24 are arranged, with the S-pole of each second magnet 24 positioned to face the N-pole of an associated first magnet 22 and the N-pole of each second magnet 24 positioned to face the S-pole of an associated first magnet 22.

In the sputtering apparatus of this embodiment, the closed circuit moving unit 30 is positioned under the target 12, and is used for moving the closed circuit unit 20 in one direction along an elliptical track parallel to the surface of the target 12 during a sputtering process. As shown in FIGS. 2 and 3, the closed circuit moving unit 30 comprises an attachment chain 32, with the closed circuits 21 of the circuit unit 20 regularly seated along the chain 32 to form an elliptical movable closed circuit loop. In order to move the chain 32 along with the closed circuits 21, the closed circuit moving unit 30 also comprises a motor-operated drive roller and a driven roller, with the chain 32 wrapped around the two rollers. The above drive roller of the closed circuit moving unit 30 is rotatably held by a motor shaft 36 extending from a drive motor 34, thus being rotated by the rotating force of the motor 34. An UCFL bearing unit 38 supports the drive roller around the motor shaft 36 so as to allow a smooth rotation of said drive roller.

In the sputtering apparatus of this embodiment, the tension control unit 40 appropriately controls the tension of the circuit unit 20 while overcoming the repulsion force acting between the permanent magnet closed circuits 21 of the circuit unit 20, and allows the closed circuits 21 to move in parallel to the surface of the target 12 while maintaining a desired parallel space between the closed circuits 21 and the target 12. This tension control unit 40 comprises a tension adjusting bolt 41, which controls the interval between the shafts of the drive and driven rollers of the closed circuit moving unit 30 so as to maintain a desired tension of the elliptical closed circuit loop. In order to allow a smooth rotation of the driven roller of the closed circuit moving unit 30 during a tension adjusting operation of the unit 40, the tension control unit 40 also has an UCT bearing unit 46, which holds the driven roller around a shaft. The tension control unit 40 further comprises two longitudinal guides 42 mounted along two guide brackets 44 so as to allow the UCT bearing unit 46 to be linearly movable in a desired direction under the guide of the two longitudinal guides 42.

In the present embodiment, a shielding unit may be preferably and selectively installed at a position above the target 12 so as to intercept ions discharged from both the cooling unit 16 and the target 12 and prevent an undesired fracture of the insulating target seat 14 due to the ions. In such a case, it is preferable to set the shielding unit with a height difference of about 1 mm formed between the shielding unit and the surface of the target 12.

The operational effect of the sputtering apparatus of this embodiment during a sputtering process will be described herein below.

A desired target 12, selected from metal targets of titanium (Ti), chrome (Cr), aluminum (Al), copper (Cu) or zirconium (Zr), or ceramic targets of indium tin oxide (ITO) or aluminum oxide (alumina, Al₂O₃), is primarily seated on the target seat 14. Thereafter, a selected sputtering gas, such as argon gas, is supplied into a sputtering chamber, while a high electric charge is applied to the target 12. In response to the application of the high electric charge to the target 12, the target 12 discharges electrons. The discharged electrons form a high-density electron concentrating area while performing both a swirling motion and a hopping motion on a predetermined portion of the target 12 due to the electric field formed by the permanent magnet closed circuit unit 20.

At the high-density electron concentrating area, the electrons collide with the argon sputtering gas, thus generating argon cations. The argon cations collide with the surface of the target 12, thus etching the target 12. When the target 12 is etched as described above, the target 12 dislodges atoms and ions from its surface. The atoms and ions from the target 12 are deposited on the entire surface of the substrate positioned opposite to the target 12, thus forming a desired thin coating on the surface of the large-scaled substrate.

During a formation of the thin coating on the entire surface of the substrate, the attachment chain 32 of the closed circuit moving unit 30 moves in one direction along the elliptical track parallel to the surface of the target 12, and so the permanent magnet closed circuits 21 of the circuit unit 20 moves in the same direction along with the chain 32.

Due to the movement of permanent magnet closed circuits 21 of the circuit unit 20, the magnetron discharge tracks, formed on the surface of the target 12 at positions corresponding to the closed circuits 21, continuously move along the surface of the target 12 in the same direction as that of the closed circuits 21. That is, the magnetron discharge tracks continuously moves from one end to the other end of the target 12 without being stopped during a sputtering process. The target 12 is thus uniformly etched on its surface without being partially and heavily etched, and allows a uniform thin coating to be formed on the entire surface of the large-scaled substrate seated on the substrate holder.

As described above, the present embodiment provides a planar-type magnetron sputtering apparatus capable of forming a uniform thin coating on the entire surface of a substrate having a large area. This sputtering apparatus has a closed circuit moving unit, which moves a plurality of permanent magnet closed circuits in one direction along an elliptical track parallel to the surface of the target during a sputtering process. The apparatus thus allows the target to be uniformly etched on its surface, and so it is possible to form a desired uniform thin coating on the entire surface of a substrate having a large area. The apparatus also improves the using efficiency of the expensive target to a desired level of higher than 60% since the target is uniformly etched on its surface due to the unidirectional movement of the permanent magnet closed circuits.

In an operation of this sputtering apparatus, the permanent magnet closed circuits are designed to be moved in one direction at a desired high speed, and so it is possible to lengthen the expected life span of a drive motor for the permanent magnet closed circuits.

In the sputtering apparatus of this embodiment, a unidirectional motor in place of a conventional reversible motor as the drive motor, and so the target is uniformly etched on its surface for the same discharge time regardless of the portions of the target from one end to the other end during a sputtering process. The using efficiency of the expensive target is thus improved.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A planar-type magnetron sputtering apparatus, comprising:
a target seat used for seating and holding a target thereon in addition to insulating said target from surroundings;
a permanent magnet closed circuit unit consisting of at least two permanent magnet closed circuits, and used for applying an electric field to said target; and
a closed circuit moving unit used for continuously moving said permanent magnet closed circuit unit in one direction along an elliptical track parallel to a surface of said target.

2. The planar-type magnetron sputtering apparatus according to claim 1, further comprising a tension control unit controlling a tension of said permanent magnet closed circuit unit while overcoming a repulsion force acting between said permanent magnet closed circuits, and allowing the permanent magnet closed circuits to maintain a desired parallel space between the closed circuits and a back surface of said target.

3. The planar-type magnetron sputtering apparatus according to claim 2, wherein said tension control unit comprises:
a tension adjusting bolt controlling an interval between drive and driven shafts of said closed circuit moving unit so as to maintain a desired tension of said permanent magnet closed circuit unit;
an UCT bearing unit holding the driven shaft of said closed circuit moving unit so as to allow a smooth rotation of said driven shaft during a tension adjusting operation of the tension adjusting bolt; and
a longitudinal guide mounted along a guide bracket, said longitudinal guide being used for linearly guiding said UCT bearing unit in a desired direction during a movement of the UCT bearing unit.

4. The planar-type magnetron sputtering apparatus according to claim 2, wherein said closed circuit moving unit comprises:
an elliptical attachment chain regularly seating said permanent magnet closed circuits thereon;
a drive motor generating a rotating force for moving said attachment chain along with the permanent magnet closed circuits;
drive and driven shafts holding said attachment chain while moving said chain using the rotating force of the drive motor; and
an UCFL bearing unit supporting the drive shaft so as to allow a smooth rotation of said drive shaft.

5. The planar-type magnetron sputtering apparatus according to claim 1, wherein each of said permanent magnet closed circuits of the closed circuit unit comprises:
two first permanent magnets closely arranged at a central portion of the permanent magnet closed circuit;
four second permanent magnets arranged in the permanent magnet closed circuit at positions around said two first permanent magnets; and
a plurality of nonmagnetic spacers arranged between said first and second permanent magnets so as to maintain a desired space between the first and second permanent magnets.

6. The planar-type magnetron sputtering apparatus according to claim 5, wherein said two first permanent magnets are arranged such that their N-poles and S-poles are positioned at the same directions, and said four second permanent magnets are arranged such that the S-pole of each of said second magnets is positioned to face the N-pole of an associated first permanent magnet and the N-pole of each of said second permanent magnets is positioned to face the S-pole of an associated first permanent magnet, thus allowing an attraction force to act between the first and second permanent magnets.

7. The planar-type magnetron sputtering apparatus according to claim 5, wherein each of said first and second permanent magnets is made of a neodymium-iron based alloy or a samarium based alloy and has a surface magnetic field of higher than about 2,000 Gauss.

8. A planar-type magnetron sputtering apparatus, comprising:
a target seat used for seating and holding a target thereon in addition to insulating said target from surroundings;
a cooling unit used for cooling said target;
a permanent magnet closed circuit unit consisting of at least two permanent magnet closed circuits, and spaced apart from a back surface of said target by a predetermined gap, and used for applying an electric field to said target; and
a closed circuit moving unit used for continuously moving said permanent magnet closed circuit unit in one direction along an elliptical track parallel to the back surface of said target.

9. The planar-type magnetron sputtering apparatus according to claim 8, further comprising a tension control unit controlling a tension of said permanent magnet closed circuit unit while overcoming a repulsion force acting between said permanent magnet closed circuits, and allowing the permanent magnet closed circuits to maintain a desired parallel space between the closed circuits and the back surface of said target.
